(19) United States
(12) Patent Application Publication
(10) Pub. No.: US 2015/0040978 A1
(43) Pub. Date: Feb. 12, 2015

(54) SOLAR-CELL EFFICIENCY ENHANCEMENT USING METASURFACES

(71) Applicant: Purdue Research Foundation, West Lafayette, IN (US)

(72) Inventors: Vladimir M. Shalaev, West Lafayette, IN (US); Alexandra Boltasseva, West Lafayette, IN (US); Mark Brongersma, Palo Alto, CA (US); Alexander V. Kildishev, West Lafayette, IN (US); Nathaniel Kinsey, Lafayette, IN (US)

(73) Assignee: Purdue Research Foundation, West Lafayette, IN (US)

(21) Appl. No.: 14/454,709

(22) Filed: Aug. 7, 2014

Related U.S. Application Data
(60) Provisional application No. 61/862,995, filed on Aug. 7, 2013.

(51) Int. Cl. H01L 31/052

(52) U.S. Cl. CPC H01L 31/0524
USPC 136/256

(57) ABSTRACT

A solar-energy module is disclosed. The module includes a first electrode configured to receive incident visible light with a different refractive index than the medium through which light travels prior to becoming incident on the first electrode, the first electrode having a first metasurface arrangement formed through the first electrode, and configured to selectively i) match the optical impedances of the first electrode and the medium, and ii) cause light to be refracted substantially away from normal refraction angle, a photon-absorbing material coupled to the first electrode on a first surface of the photon-absorbing material and configured to receive refracted light through the first electrode and adapted to produce an electrical current in response to the refracted light, length of the photon absorbing material substantially larger than thickness of the photon-absorbing material, and a second electrode coupled to the photon-absorbing material on a second surface of the photon-absorbing material.

### CROSS-REFERENCE TO RELATED APPLICATIONS

The present U.S. patent application is related to and claims the priority benefit of U.S. Provisional Patent Application Ser. No. 61/862,995, filed Aug. 7, 2013, the contents of which are hereby incorporated by reference in their entirety into the present disclosure.

### TECHNICAL FIELD

The present application relates to solar cells, and specifically to improving absorption of incident light in solar cells.

### BACKGROUND

This section introduces aspects that may help facilitate a better understanding of the disclosure. Accordingly, these statements are to be read in this light and are not to be understood as admissions about what is or is not prior art.

A solar cell is a photoelectric conversion device that transforms solar energy into electrical energy. Solar cells are generally divided into two categories: 1) bulk solar cells and 2) thin film solar cells. Typically bulk solar cells are based on thickness of 200 μm or greater. On the other hand, thickness of thin film solar cells typically ranges between a few nm to tens of μm. A thin film solar cell is typically silicon-based including amorphous silicons, microcrystalline silicons, and polycrystalline thin-film silicons, as well as thin-film solar cells based on compounds including Cu(InGa)Se₂, CdTe, and CuInSe₂.

A solar cell produces electrical energy by transferring electrons and holes to n-type and p-type semiconductors, respectively, and then collecting electrons and holes in each corresponding electrode, when an electron-hole pair is produced by solar light energy absorbed in a photoactive layer inside the semiconductors. A thin film solar cell has a high light absorption rate in the visible light region compared to the crystalline solar cell. Therefore, for solar cells, it is important to effectively absorb solar energy emitted from the sun, and to increase efficiency of the solar cell absorbing and using the solar energy from the sun.

Referring to one exemplary embodiment of the solar cells found in the related art, FIG. 1 depicts a cross section view illustrating a related art thin film type solar cell 1. As shown in FIG. 1, the related art thin film type solar cell 1 typically includes a substrate 2; a front electrode layer 3 on the substrate 2; a semiconductor layer 4 on the front electrode layer 3; a transparent conductive layer 5 on the semiconductor layer 4; and a back electrode layer 6 on the transparent conductive layer 5. The transparent conductive layer 5 and the back electrode 6 can be one and the same.

Waves which are incident upon an interface can experience basic phenomenon such as reflection and refraction. The direct outcome of these effects depends upon the basic properties of the materials at the interface. Researchers have long used these properties of reflection and refraction to develop extraordinary technologies such as waveguides and polarization filters, but in many cases these, effects limit the performance of a system. For solar cells formed from various semiconductor materials, there is an inherent and large mismatch between the basic material properties of the structure and the surrounding air. This impedance mismatch causes a significant reflection to occur at this interface, significantly reducing the amount of light which can be coupled into the device.

Referring to FIG. 2, the impedance mismatch between air and the back electrode 6 and air. Incident light 11in enters the solar cell 1 through the back electrode 6. Light is then refracted as indicated by 11rf and reflected as indicated by 11rl. The refracted light 11rf travels through the solar cell and strikes the front electrode 3 at which point reflects as indicated by 12rl and then disadvantageously exits the solar cell as indicated by 12o. The light that exits (i.e., 12o) and the light that is reflected (i.e., 11rl) negatively contribute to the inefficiency of the solar cell 1.

Methods for increasing the efficiency of the thin film solar cell include mounting a rear reflection structure on a solar cell. Rear reflection structure may increase the efficiency by reducing or effectively preventing light entering through a front surface of a solar cell from going out of the solar cell through the rear surface, and using the remaining light reflected by the rear reflection structure in the photoactive layer of the cell.

The other contributor is unwanted reflection. The large difference in impedance between the semiconductor solar cell and air causes a substantial amount of light to be reflected (i.e., 11rl as shown in FIG. 2). Also, light not incident at a nearly normal angle may not enter the solar cell if impedance is mismatched. If it does not, it will simply be reflected. As a way to compensate for the unwanted reflection, solar cells typically move throughout the day to ensure approximately normal incidence with sunlight to improve efficiency. The matching of impedance also allows light with a larger angle of incident to effectively couple into the cell where it would have otherwise experienced reflection at the interface.

On way to increase the in-coupling of light includes utilization of an impedance matching arrangement with air. This method has been demonstrated in several ways including gratings, antireflection coatings, graded index layers, or the use of small metallic structures to gradually increase the impedance from air to that of the solar cell. Anti-reflection coatings use destructive interference to effectively cancel any reflected energy, consequently improving the transmitted energy. Anti-reflective coatings are very sensitive to the wavelength but have been shown to be quite effective. Face reflections as low as 0.01% have been achieved for antireflection (AR) coatings on semiconductor lasers. Gratings reduce reflections by attempting to match the impedance between the materials at the interface with structures that are similar to the size of the wavelength. They can be made more tolerant to the changes in wavelength and may be polarization dependent. In general, gratings also have a limitation in that they consider only a change in the effective permittivity of the medium since the permeability of the constituent materials in the optical regime is that of air. Gradient index layers provide more flexibility, allowing researchers to engineer the conditions at an interface by controlling the composition of constituent materials. Reflections are reduced by forming a smooth index transition between two materials over several wavelengths. These coatings can provide a significant suppression of reflections over a broad range. However, because solid materials have refractive indices greater than that of air, a small but abrupt change in the refractive index with air limits the total efficiency of the structure. Small metallic structures have been used to generate an impedance match. However, the use of metallic spheres or squares only allows for an approximate impedance match using permittivity.

There is, therefore, an unmet need for a solar cell construction that reduces reflection and one which further improves absorption of light.

### SUMMARY

A solar-energy module is disclosed. The module includes a first electrode configured to receive incident visible light with a different refractive index than the medium through which light travels prior to becoming incident on the first electrode, the first electrode having a first metasurface arrangement formed through the first electrode, and configured to selectively i) match the optical impedances of the first electrode and the medium, and ii) cause light to be refracted substantially away from normal refraction angle, a photon-absorbing material coupled to the first electrode on a first surface of the photon-absorbing material and configured to receive refracted light through the first electrode and adapted to produce an electrical current in response to the refracted light, length of the photon absorbing material substantially larger than thickness of the photon-absorbing material, and a second electrode coupled to the photon-absorbing material on a second surface of the photon-absorbing material.

### BRIEF DESCRIPTION OF THE DRAWINGS

The above and other objects, features, and advantages of the present invention will become more apparent when taken in conjunction with the following description and drawings wherein identical reference numerals have been used, where possible, to designate identical features that are common to the figures, and wherein:

FIG. 1 depicts a cross section view illustrating a related art thin film type solar cell;

FIG. 2 depicts the solar cell of FIG. 1 with exemplary incident, reflected, and refracted light rays;

FIG. 3 depicts an exemplary metasurface supercell, according to the present disclosure;

FIG. 4 depicts an exemplary array of supercells of FIG. 3 for improved impedance matching in order to minimize unwanted reflection;

FIG. 5 depicts and exemplary schematic of incident, reflective, and refractive rays across a material interface with phase discontinuity and gradient of phase dφ/dy;

FIG. 6 depicts induced conduction current and induced displacement current in the presence of incident electric field and incident magnetic field;

FIG. 7 depicts an exemplary array of inverted supercells of FIG. 3 for an improved reflection angle substantially larger than normal reflection angle;

FIG. 8 depicts an array of inverted supercell structures;

FIG. 9 depicts an exemplary solar cell according to the present disclosure; and

FIGS. 10a, 10b, 11a and 11b depict process steps and a flow chart describing an exemplary manufacturing process for making the solar cell according to the present disclosure.

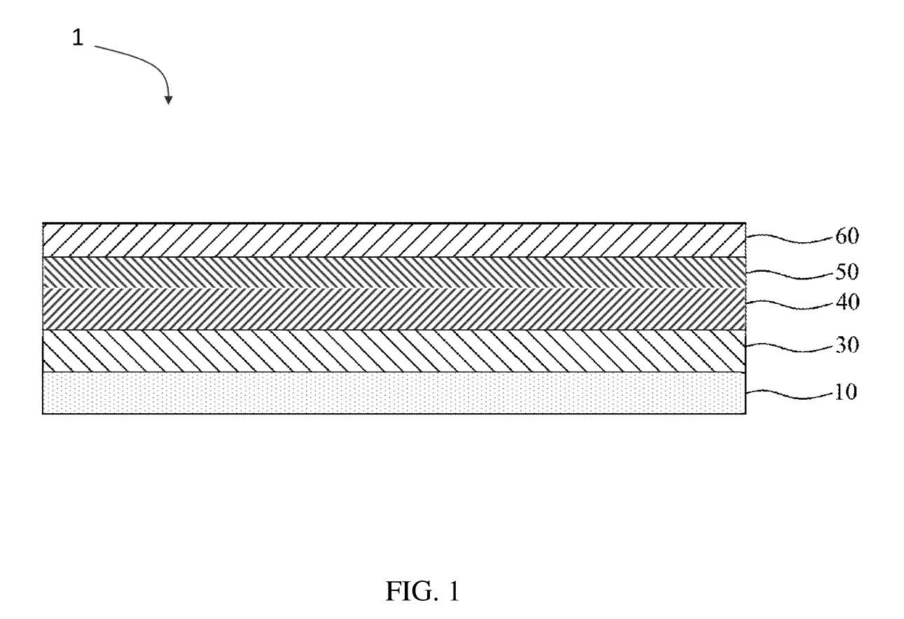

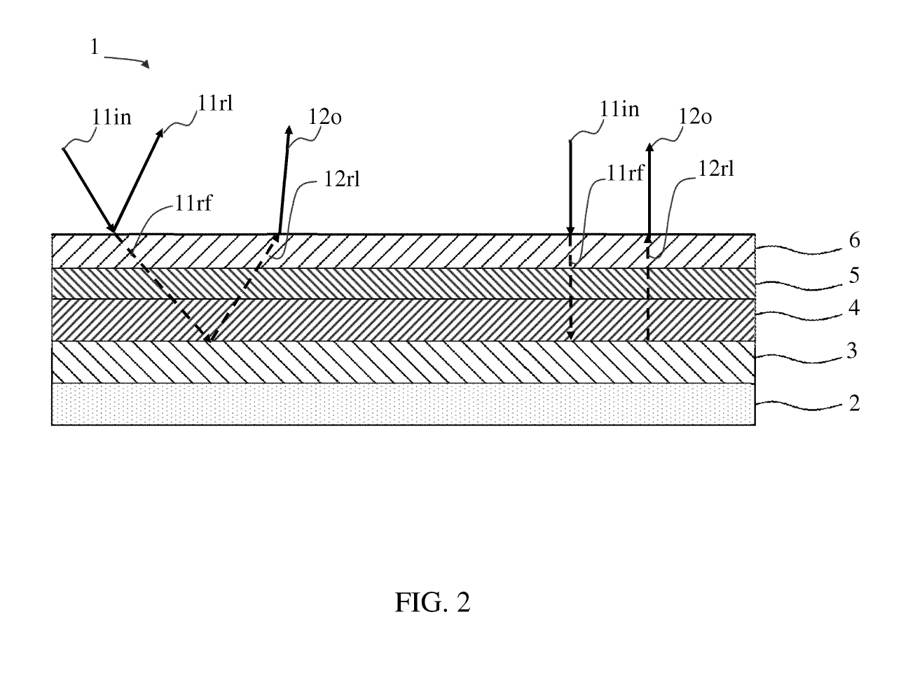

The attached drawings are for purposes of illustration and are not necessarily to scale.

### DETAILED DESCRIPTION

For the purposes of promoting an understanding of the principles of the present disclosure, reference will now be made to the embodiments illustrated in the drawings, and specific language will be used to describe the same. It will nevertheless be understood that no limitation of the scope of this disclosure is thereby intended.

A novel approach for avoidance of unwanted reflection and improvement in absorption in solar cells is disclosed. The approaches provided in the present disclosure ensure that substantially all light which does enter the solar cell is absorbed and converted to electrical energy. As a result, light which enters is absorbed within twice the thickness of the cell. For thin-film solar cells, this length-feature can be quite small, on the order of a few microns. In addition, the present disclosure describes use of metasurface to achieve superior impedance matching and light directing to further prevent light from escaping the cell. These metasurfaces differ from the previously utilized roughened back surface which used grating or photonic crystals, thereby the metasurfaces do not rely on scattering or on an abrupt change in only the permittivity in order to reduce unwanted reflection.

Instead Metasurfaces improve the efficiency of the solar cells by tailoring both the permittivity and permeability of an effective layer to achieve an impedance match between the materials at an interface. Metasurfaces can also be designed to provide a polarization independent design as well as structures which are deeply sub-wavelength and require relatively simple scalable chemical or lithographic nanofabrication processes such as etching or nano-imprint lithography, adhesion lithography, or another soft lithography method. The application of a metasurface to a semiconductor-air interface will result in essentially no light being reflected, facilitating and increasing in the in-coupled light efficiency. Metasurfaces could even be used in conjunction with current methods (i.e., grating or photonic crystals) to further reduce the reflection for a narrow band, or generate effective wideband antireflection surfaces.

Consequently, through the use of metasurfaces, the properties of an effective material can be designed to generate an impedance match between the low impedance surrounding and the high impedance solar cell. The application of this metasurface can greatly reduce the reflection at the interface, increasing the amount of light coupled into the solar cell.

Metasurfaces have gained significant attention due to their relative ease in fabrication when compared to their 3-D counterparts. They are traditionally fabricated using patterned metallic structures on a dielectric, or voids in metallic films. However, they are not limited to metals only. Semiconductors can, in principle, also be used as a base material for nano structures. For many applications these structures are more desirable because they do not suffer from the large ohmic losses which plague metallic metasurfaces.

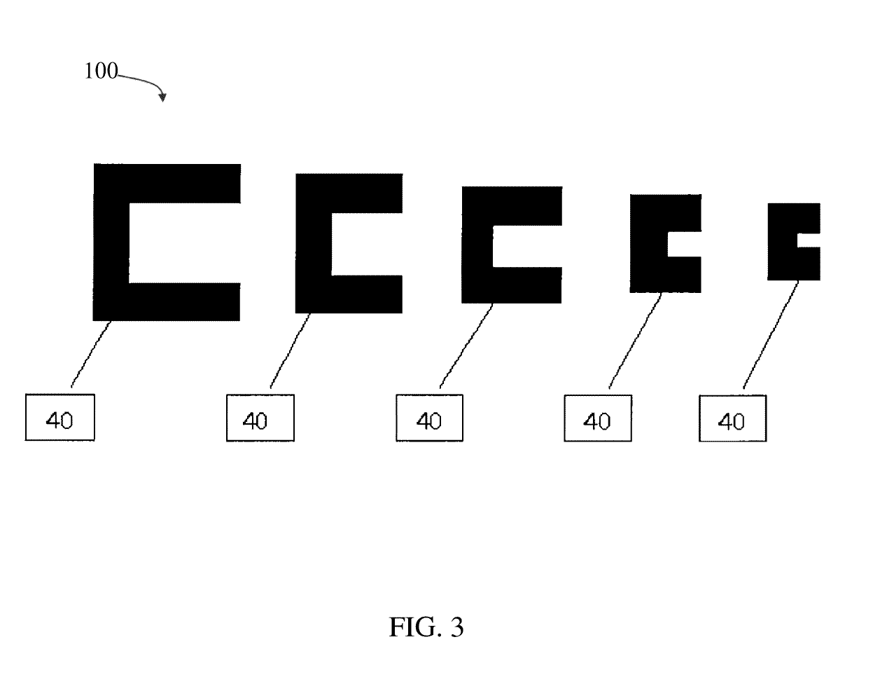

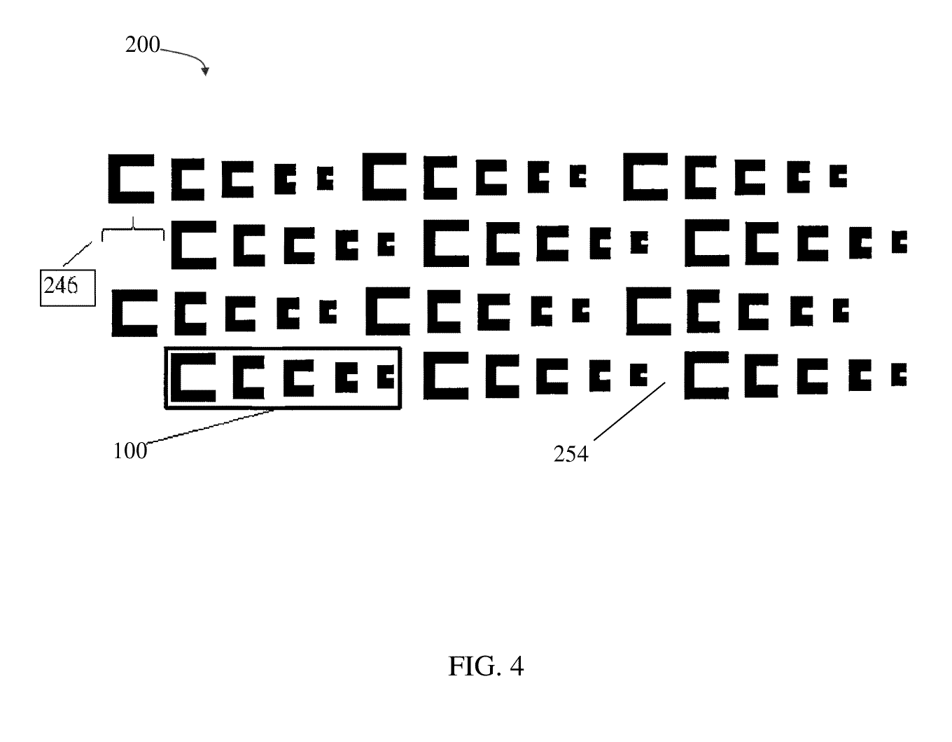

An exemplary metasurface arrangement in form of a supercell 100 according to the present disclosure is provided in FIG. 3. The supercell 100 includes an array of “C” shaped structures that can be placed on the back surface of a solar cell. While the supercell 100 is depicted to include 5 “C” shaped structures 40 (also referred to herein as resonant structures) of varying sizes aligned according to a longitudinal axis (not shown), the number of structures can be more or less that 5, the shape of the structures can be any structure with an asymmetry about an imaginary plane orthogonal to the structure, the alignment of the structures can be provided in a unitary angular fashion or random altogether, the sizes of each structure can be progressively smaller or provided in a random fashion. Referring to FIG. 4, an array 200 of the supercells 100 is depicted, in one exemplary arrangement to be disposed on the back surface of a solar cell. The array 200 is constructed of a sheet of dielectric 254 with metallic structures formed therein, where the spacing between the supercells is identified as 246.

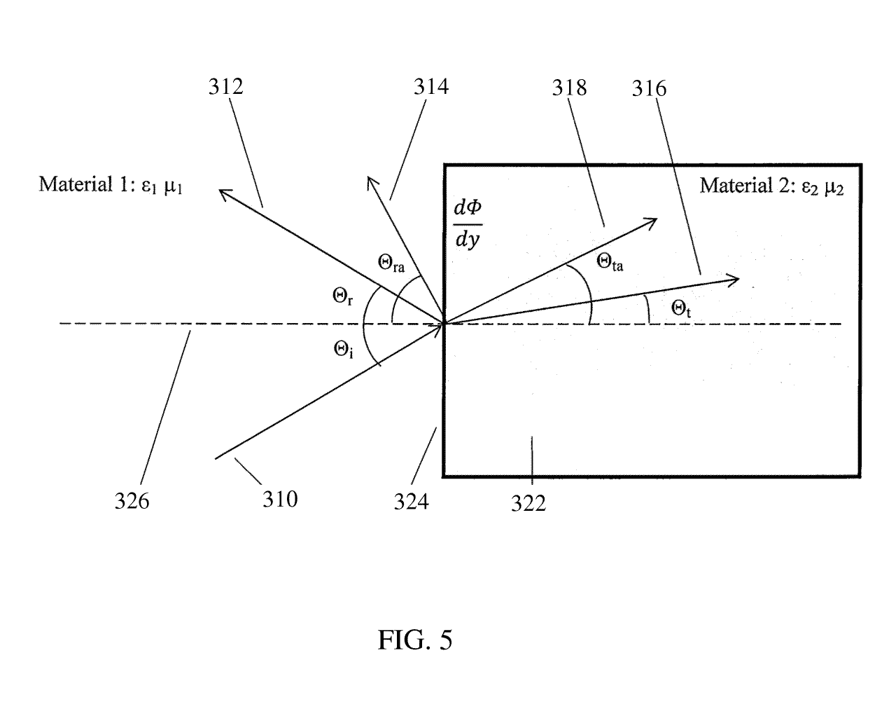

At a metasurface, the generalized reflection and refraction conditions are given by Eq. 1 and Eq. 2:

$$\begin{matrix}\sqrt{{μ}_{2} {ɛ}_{2}} sin ( {θ}_{t} ) - \sqrt{{μ}_{1} {ɛ}_{1}} sin ( {θ}_{i} ) = \frac{{λ}_{0}}{2 π} \frac{d Φ}{d y} & ( 1 ) \\ sin ( {θ}_{r} ) - sin ( {θ}_{i} ) = \frac{{λ}_{0}}{2 π \sqrt{{μ}_{1} {ɛ}_{1}}} \frac{d Φ}{d y} & ( 2 )\end{matrix}$$

where dφ/dy is the gradient of phase discontinuity along an air-solar cell interface, μ is the permeability of the material, ε is the permittivity of the material, and λ₀ is the free space wavelength of the incident wave. The angular relationships in the above equations are depicted in FIG. 5. FIG. 5 depicts incident light 310 that is incident on material interface with phase discontinuity and gradient of phase dφ/dy 324, with a normally reflected light ray 312, as well as anomalously reflected light ray 314. The incident light 310 also results in normally transmitted (refracted) light ray 316, as well as anomalously transmitted (refracted) light ray 318, all of the above are with respect to surface interface 326.

The depiction of a wave incident upon a metasurface shows that there are two reflected and refracted beams, Θᵣ, Θᵣₐ, Θₜ, and Θeₜₐ which are the normal and anomalous reflections and the normal and anomalous refractions respectively. Normal reflections and refractions occur due to the periodicity of the structure. Therefore, at certain distances y, the difference in phase between the two points is dφ/dy=0. This is the traditional case of reflection and refraction. At all other points there is a discrete difference in the phase between two incident rays which leads to the anomalous reflection and refraction.

Through the use of metasurfaces, it is suggested that an impedance match can be engineered between the high impedance semiconductor light source and low impedance air. This approach is unique from previous works using bulk materials or patterned structures as metasurfaces allow us to control both the permittivity and permeability of the material at a deeply subwavelength scale.

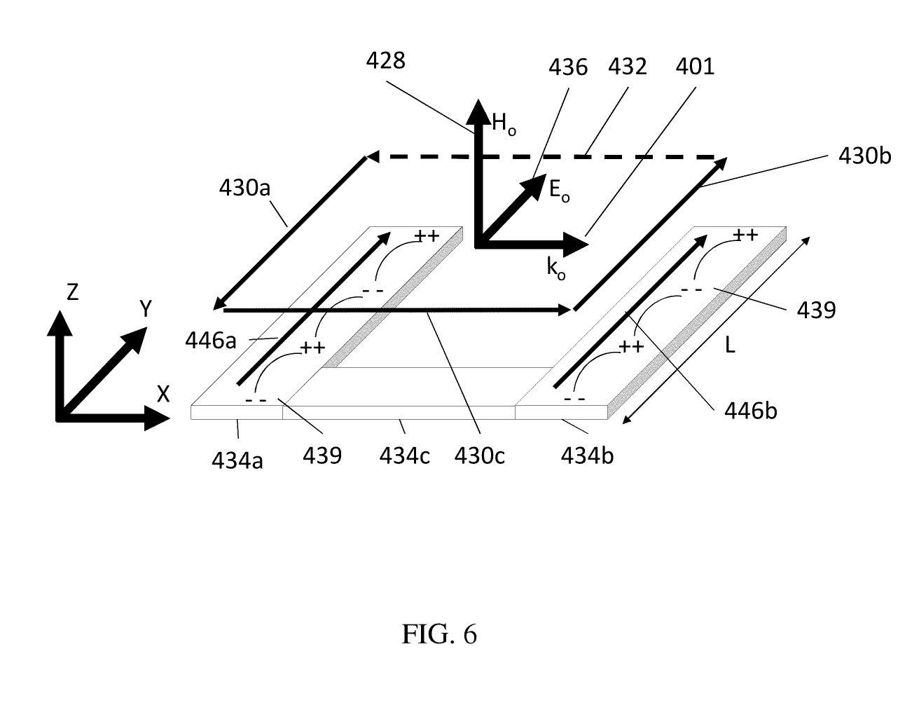

The metasurface tailors impedance by employing resonance for both the electric and magnetic fields incident on the material. A depiction of an exemplary “C-shaped” structure having two metallic strips of length L=2a separated by a dielectric of thickness d is shown in FIG. 6. It should be appreciated that the relationship provided below are for parallel strips and not necessarily for the “C-shaped” structure depicted in FIG. 6. As depicted, for an incident wave k₀ 401 in the X-direction, a magnetic field H₀ 428 (in the Z direction) generates a loop current based on the material magnetic response on the surface of the structure including induced conduction currents 430a, 430b, and 430c on metal nanostructures 434a, 434b, and 434c respectively, with an induced displacement current 432 between the metal nano structures 434a and 434b, completing the loop. This arrangement gives rise to a magnetic resonance which varies with the geometry of the structure and the base material parameters of the metal. Furthermore, material response to the electric field (in the Y direction) induces the conduction current 446a and 446b. This arrangement gives rise to an electric resonance as identified by the surface plasmon resonance 439 which varies with the geometry of the structure and the base material parameters of the metal. The magnetic moment for two cylindrical nanowires is given by Eq. 3 with the resonant condition given by Eq. 4.

$$\begin{matrix}m = \frac{1}{2} {H}_{0} {a}^{3} ln ( \frac{d}{b} ) {( kd )}^{2} \frac{tan ( ga ) - ga}{{( ga )}^{3}} & ( 3 ) \\ ga \approx \frac{a}{b} \sqrt{2 ln ( \frac{d}{b} ) \vert {ɛ}_{m} ( ω ) \vert} = \frac{π}{2} & ( 4 )\end{matrix}$$

where, H₀ is the applied magnetic field,
a is half the length L of the nanowire,
d is the separation of the nanowires,
b is the radius of nanowire, and
k is the wave vector ω/c. The factor ga is provided in equation 4.

Consequently, as depicted in FIG. 6, for a wave traveling in the X-direction, the electric field Eₒ in the Y-direction excites a surface plasmon resonance for the structures. The induced electric dipole in the i^{th} direction for an ellipsoid with axis lengths of a, b, and c is given by Eq. 5 where Eₒ is the applied field 436, n are real numbers which depend on the ellipsoid geometry, and εₘε_{d} are the metal and dielectric permittivities respectively. By adjusting these resonances, the effective permittivity and permeability of the structure can be designed allowing for a near-perfect impedance match between the semiconductor light source and air. While there are many possible metamaterial structures which can provide both electric and magnetic resonances, they function in a similar manner. More complex geometries, such as c-shaped, v-shaped, T-shaped, and others are verified and optimized through numerical simulation.

$${p}_{i} = \frac{1}{3} abc \frac{( {ɛ}_{m} - {ɛ}_{d} )}{{ɛ}_{d} + {n}_{i} ( {ɛ}_{m} - {ɛ}_{d} )} {E}_{o} \qquad ( 5 )$$

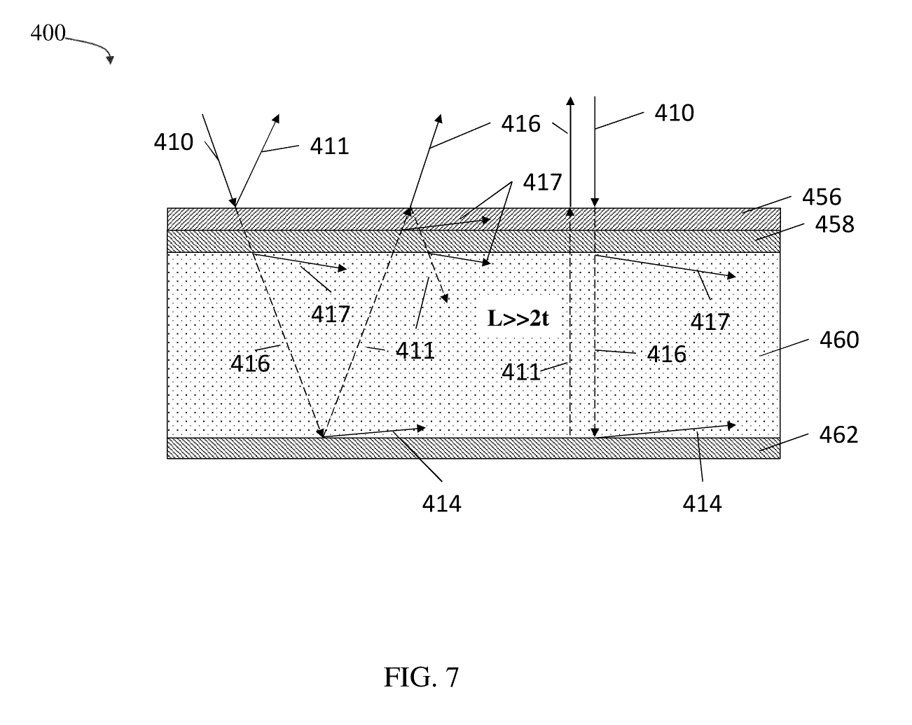

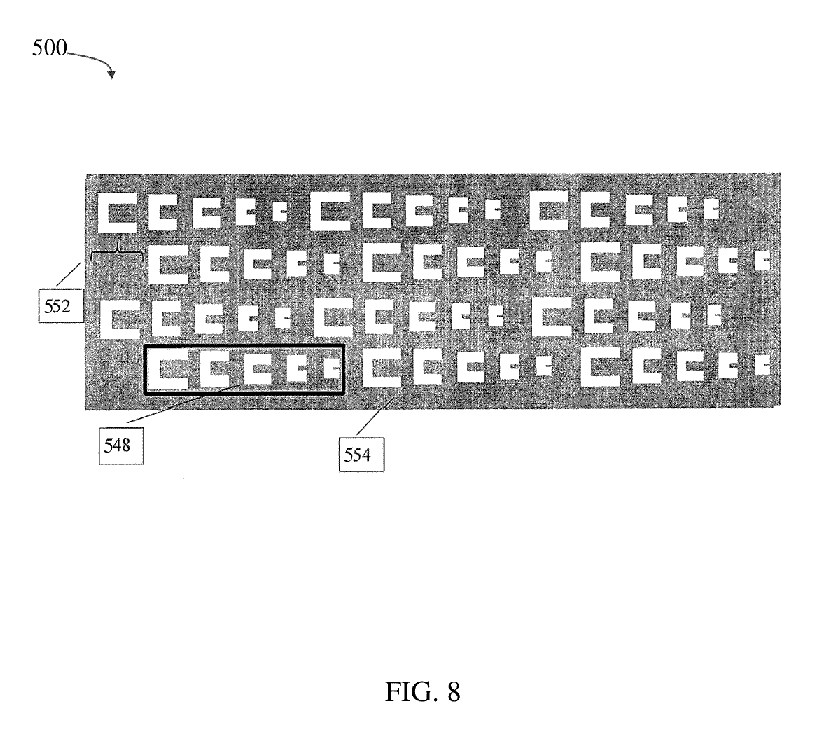

Referring to FIG. 7, a schematic illustration of a metasurface used to increase the light coupled into a solar cell 400 by impedance matching and refraction control is provided. The solar cell 400 includes a substantially transmissive film 458 which is used to match impedance at the top surface and a substantially reflective film 462 is used to anomalously reflect light at the bottom surface. The transmissive film 458 can be a conventional in-coupling structure or a metasurface (metallic structures or voids in other wise a dielectric sheet), as provided in FIG. 4. The reflective film 462 can also be a metasurface as provided in FIG. 8 (which are dielectric structure or voids in an otherwise metallic sheet). The transmissive film 458 can be configured to selectively i) impedance match to avoid unwanted reflection 411, and ii) generate refraction substantially off normal refraction (i.e., anomalous refraction) 417 to keep the light inside the cell 400. The anomalous refraction 417 (as compared to normal refraction 416) causes light to travel a significant distance through the solar cell material 460 allowing a significant amount of absorption by the solar cell material 460. Since the transmissive film 458 impedance matches, light can get out through 458 as well as getting in. The reflective film 462 reflects ray 414 (also referred to as anomalously reflected light), which is far off-normal (normal reflection is identified as 411) and travels a significant distance through the solar cell material 460 allowing a significant amount of absorption by the solar cell material 460. Normal reflection 411 inside the cell 400 is desirable, while normal reflection 411 outside the cell 400 is not. The distance rays 414 travels (i.e., L), is much greater than twice the thickness t of solar cell material 460. In comparison, 2t is typically the distance a normally-incident ray travels through a conventional solar cell with a reflective back surface. In FIG. 7, the incident light is 410 and the refracted light is 416. The normally reflected light is 412.

The angle of anomalous reflection does depend on incident angle. Resonances are a function of projections of rays on the plane of the surface. Therefore, the reflective film 462 with metasurfaces can be designed to reduce the extent to which rays are reflected out of the cell. For example, the reflective film 462 with metasurfaces can be designed to control electric (E) field. Near normal, the E-field is in the plane of the reflective film 462. Far from normal, the E-field is almost perpendicular to the reflective film 462. The reflective film 462 with metasurfaces can be designed so that, as the incident angle moves away from the normal, less light is reflected anomalously and more is reflected by Snell's law. In this way, the angle of reflection will be far from normal across a wide range of incident angles.

The solar cell and its metasurfaces 458 and 462 can be designed based on the typical sun angle and spectrum that a given solar cell will encounter in the field. Relevant facts can include whether or not the solar cell will be installed on a rooftop, and whether the solar cell will be fixed or mobile.

Various aspects discussed herein increase the efficiency of solar cells through the use of metasurfaces. Two metasurfaces can be used: an impedance matching layer placed on the top surface and a highly reflective metasurface placed below the solar cell. These two materials serve two purposes: 1) to increase the in-coupled light efficiency, and 2) to ensure that substantially all light which enters the solar cell is absorbed.

The impedance matching metasurface is designed to eliminate reflections for the light which is incident upon the output facet. FIG. 3 shows an example supercell of the metasurface which could be used to accomplish this impedance matched layer. The unit cell contains several individual resonant structures whose geometries are slightly modified to adjust the resonant conditions. This situation generates a dφ/dy as described for a general metasurface interface. These unit cells are the combined in arrays which may or may not be offset from row to row as shown in FIG. 4.

A highly reflective metasurface can be utilized to produce large anomalous reflections with an angle that is far from the normal. FIG. 8 is an example of an inverted form of the metasurface arrangement shown in FIG. 4 which produces a high reflectivity. The metasurface arrangement 500 of FIG. 8 includes an inverted supercell 548 (i.e., a thin film of metal with dielectric structures formed therein) including an offset provided between the inverted supercells 548 and a metallic film 554 on which the supercells are formed. This film achieves a high reflectivity because it is a thin film with small perforations. If this film is made of a high impedance material, a large reflection will be observed. This metasurface is designed to produce an anomalous reflection which is close to 90° to greatly increase the interaction length between the light and the solar cell. This ensures that the vast majority of light that enters the solar cell is absorbed by the system to be converted into electricity. The highly reflective metasurface is placed below the solar cell. If the highly reflective metasurface is made of a metallic film, this layer could also serve as an electrical contact for the solar cell.

The impedance matching metasurface 458 (see FIG. 7) is depicted as being placed on conventional layer to reduce reflections, generating enhanced in-coupling. However, this metasurface could also be placed directly onto the solar cell in place of the conventional layer.

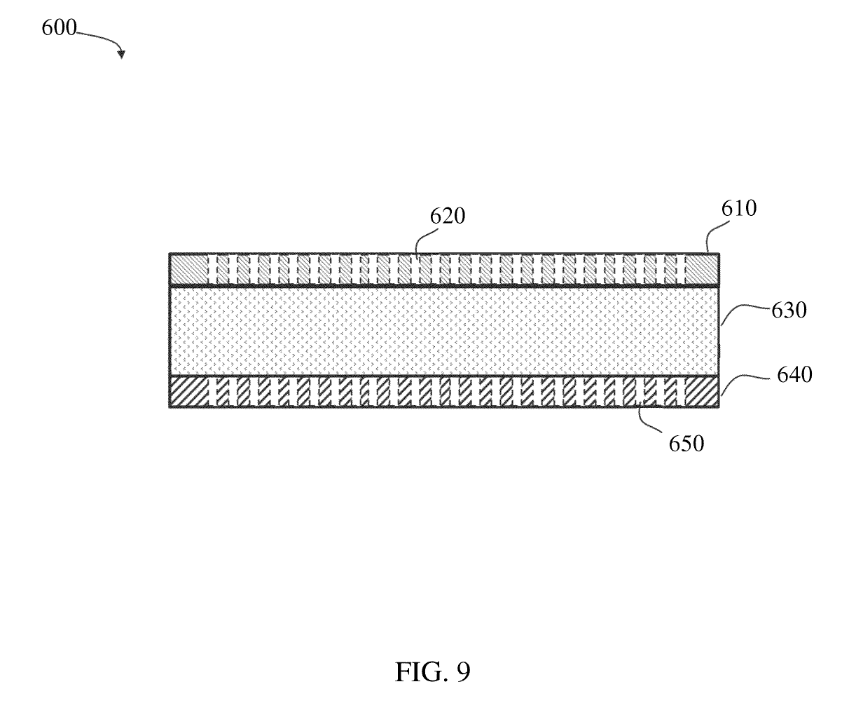

Referring to FIG. 9, a solar cell 600 is depicted. The cell 600 includes a transmissive layer 610 with metasurfaces 620 provided therethrough coupled to photon-absorbing material 630 over a reflective layer 640 with metasurface 650 provided therethrough. The transmissive layer 610 is configured to selectively i) impedance match the medium above the transmissive layer 610 layer (typically air) to the photon-absorbing material 630 to avoid unwanted reflection (see FIG. 6) , and ii) generate anomalous refraction (see FIG. 6) to keep the light inside the cell 600. The reflective layer 640 is configured to generate anomalous reflection (see FIG. 6) to keep light inside the cell 600.

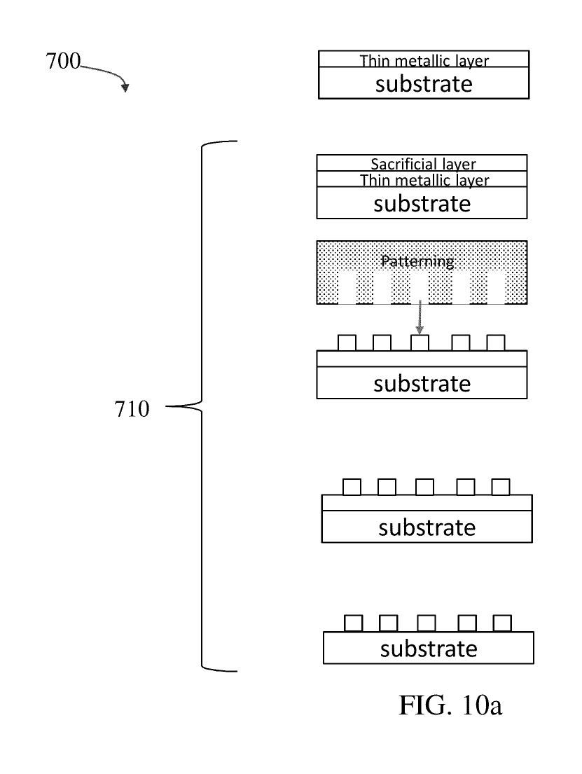

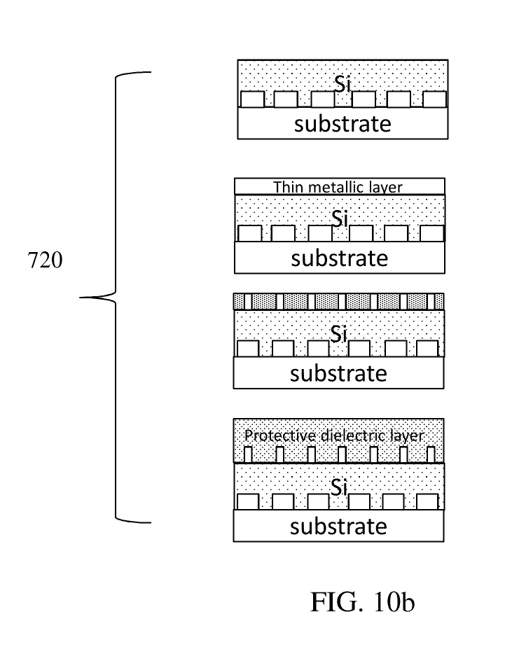

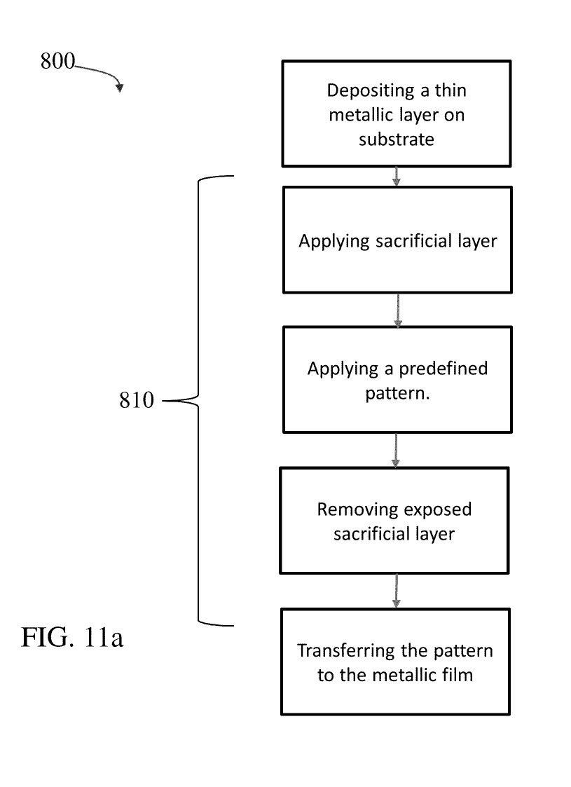

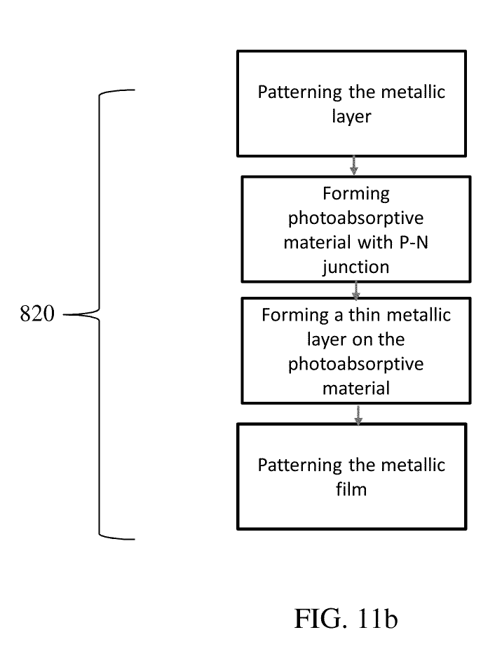

Referring to FIGS. 10a, 10b 11a and 11b, a schematic process 700 and a flow chart 800 of manufacturing the solar cell according to the present disclosure is provided. The process 700 includes depositing a thin metallic layer on a substrate followed by patterning the metallic film using standard nanofabrication techniques (e.g. photolithography, nano-imprint, electron beam, etching). The nano-imprint process is particularly depicted in FIGS. 10a and FIG. 11a and identified as the steps 710 and 810. The remainder of the steps is depicted in FIGS. 10b and 11b and are identified by the steps 720 and 820, respectively. Referring to the nano-imprint steps (710 and 810 in FIGS. 10a and 11a, respectively), a sacrificial layer is next formed on the thin metallic layer. The sacrificial layer can be e.g., a polymer or photoresist such as PMMA or AZ 1518. Next using a predefined pattern (e.g., a photomask or nano-imprint stamp) or direct writing (using electron/ion beam or light) the sacrificial layer is exposed to generate the pattern. Next using a proper chemical, the exposed polymer is removed in non-nano-imprint techniques. Next the pattern is transferred to the metallic film using standard techniques (chemical/physical etching) and the remaining sacrificial layer, removed. One metasurface is thus formed.

Referring to FIGS. 10b and 11b, the remainder of the process 700 and flow chart 800 are provided. The next includes forming a photoabsorptive material (e.g. Si, GaAs) with P-N junction over the substrate. Next a thin layer of metal is deposited over the photoabsorptive material. Next, the metallic film is patterned using standard nanofabrication techniques (e.g. photolithography, nano imprint, electron beam, etching), thus forming another metasurface. Finally, and optionally a dielectric layer could be formed to protect the surface.

According to one embodiment, the photoabsorptive material can be a semiconductor, ceramic, or other weakly/non-conducting material that has an inter-bandgap energy suitable to absorb incident sunlight. Examples include germanium, silicon, gallium arsenide, indium phosphide, gallium nitride, aluminum nitride, or other group IV (silicon, germanium), group III-V (gallium arsenide, aluminum nitride), or group II-VI (zinc oxide) combinations.

The metasurface structures can be made from metal, semiconductor, ceramic, or other material that exhibits metallic properties (i.e., real permittivity <0) in the wavelength range of operation (visible light). Example include aluminum, gold, silver, copper, nickel, tungsten, platinum, titanium, titanium nitride, zirconium nitride, indium tin oxide, gallium doped zinc oxide.

Those skilled in the art will recognize that numerous modifications can be made to the specific implementations described above. The implementations should not be limited to the particular limitations described. Other implementations may be possible.

1. A solar-energy module, comprising:
a first electrode configured to receive incident visible light, the first electrode having a different refractive index than the medium through which light travels prior to becoming incident on the first electrode, the first electrode having a first metasurface arrangement formed through the first electrode, the first metasurface arrangement configured to selectively i) match the optical impedances of the first electrode and the medium, and ii) cause light to be refracted substantially away from normal refraction angle;
a photon-absorbing material coupled to the first electrode on a first surface of the photon-absorbing material and configured to receive refracted light through the first electrode and adapted to produce an electrical current in response to the refracted light, length of the photon absorbing material substantially larger than thickness of the photon-absorbing material; and
a second electrode coupled to the photon-absorbing material on a second surface of the photon-absorbing material.

2. The solar energy module of claim 1, further comprising:
a second metasurface formed through the second electrode, the second metasurface configured to anomalously reflect at least some refracted light at an angle substantially larger than a normal reflection angle.

3. The solar energy module of claim 1, the first metasurface arrangement comprising a plurality of supercells, each supercell comprising at least one magnetic resonance structure formed based on features having feature lengths between 1 nm to 100 nm and having an asymmetry about an imaginary plane orthogonal to the structure, the structure configured such that the incident light induces at least one of a conduction current on the surface of the structure based on the electric field and a displacement current across a discontinuity on the structure based on the magnetic field.

4. The solar energy module of claim 3, the magnetic resonance structures provided as “C-shaped” structures.

5. The solar energy module of claim 3, the magnetic resonance structures provided as “V-shaped” structures.

6. The solar energy module of claim 3, the magnetic resonance structures provided as “bowtie shaped” structures.

7. The solar energy module of claim 2, the second metasurface arrangement comprising a plurality of supercells, each supercell comprising at least one magnetic resonance structure formed based on features having feature lengths between 1 nm to 100 nm and having an asymmetry about an imaginary plane orthogonal to the structure, the structure configured such that the refracted light induces at least one of a conduction current on the surface of the structure based on the electric field and a displacement current across a discontinuity on the structure based on the magnetic field.

8. The solar energy module of claim 7, the magnetic resonance structures provided as “C-shaped” structures.

9. The solar energy module of claim 7, the magnetic resonance structures provided as “V-shaped” structures.

10. The solar energy module of claim 7, the magnetic resonance structures provided as “bowtie shaped” structures.
